(19) United States
(12) Patent Application Publication
(10) Pub. No.: US 2011/0175067 A1
(43) Pub. Date: Jul. 21, 2011

(54) ORGANIC LIGHT-EMITTING DIODE

(76) Inventors: Keiji Sugi, Fujisawa-shi (JP); Akio Amano, Kawasaki-shi (JP); Isao Takasu, Tokyo (JP); Tomio Ono, Yokohama-shi (JP); Yukitami Mizuno, Tokyo (JP); Tomoaki Sawabe, Tokyo (JP); Atsushi Wada, Kawasaki-shi (JP); Shintaro Enomoto, Yokohama-shi (JP)

(21) Appl. No.: 12/875,478

(22) Filed: Sep. 3, 2010

(30) Foreign Application Priority Data
Jan. 15, 2010 (JP) 2010-007369

(51) Int. Cl. H01L 51/30

(52) U.S. Cl. 257/40; 257/E51.027

(57) ABSTRACT

According to one embodiment, there is provided an organic light-emitting diode including an anode and a cathode arranged apart from each other, an emissive layer arranged between the anode and the cathode, a hole injection layer arranged between the anode and the emissive layer and including a polyethylenedioxythiophene, and a hole-transport layer arranged between the hole injection layer and the emissive layer and including a hole-transport material. The emissive layer includes a cathode side first area including a hole transport host material, an electron transport host material and an emitting dopant, and an anode side second area including the hole transport host material and no electron transport host material.

### CROSS-REFERENCE TO RELATED APPLICATIONS

This application is based upon and claims the benefit of priority from Japanese Patent Application No. 2010-007369, filed Jan. 15, 2010; the entire contents of which are incorporated herein by reference.

### FIELD

Embodiments described herein relate generally to an organic light-emitting diode.

### BACKGROUND

In recent years, organic light-emitting diodes have been attracting attention in view of luminescence technique for next generation displays and illumination. In the early study of organic light-emitting diodes, fluorescence has been mainly used as mechanism of luminescence of an organic layer. However, in recent years, an organic light-emitting diode utilizing phosphorescence which exhibits higher internal quantum efficiency has been attracting attention. Mainstream of emissive layers utilizing phosphorescence in recent years are those in which a host material comprising an organic material is doped with an emissive metal complex including iridium or platinum as a central metal. This emissive layer and other members have been variously contrived to obtain a diode having a higher luminous efficacy.

For example, an organic light-emitting diode is proposed which is provided with a hole injection layer comprising a polyethylenedioxythiophene (hereinafter referred to also as PEDOT:PSS) to improve the ability to inject holes from the anode and to improve the flatness of a layer lying underneath. Because the solvent for PEDOT:PSS is water, an emissive layer and the like using an organic solvent can be formed. Thus, PEDOT:PSS is used particularly in many organic light-emitting diodes produced using the coating process. However, when this PEDOT:PSS is used for the hole injection layer, there is the problem that the triplet exciting energy of a phosphorescence emitting material is transferred to PEDOT:PSS and deactivated without any radiation, resulting in reduced luminous efficacy. For this, an organic light-emitting diode is proposed in which a hole-transport layer having high triplet exciting energy is inserted between PEDOT:PSS and the emissive layer. In this case, it is theoretically inferred that the transfer of triplet exciting energy from the emissive layer to the hole-transport layer is prevented and therefore high luminous efficacy is obtained by selecting materials allowing the triplet exciting energy of the hole-transport layer to be higher than that of an emitting dopant. However, we have found that the use of such a structure in which the hole-transport layer is inserted results in a significant drop in luminous efficacy.

JP-A 2007-42875 (Kokai) and JP-A 2007-134677 (Kokai) each disclose an organic light-emitting diode having a structure in which an intermediate layer only comprising a hole-transport host material is formed between the hole-transport layer and the emissive layer. The intermediate layer described in these documents has the ability to make easy to inject holes into the emissive layer. However, there is no suggestion as to the use of a PEDOT:PSS as the hole injection layer material in these documents, showing that they are different in object from the embodiments which will be described hereinafter.

### BRIEF DESCRIPTION OF THE DRAWINGS

FIG. 1 is a cross-sectional view of an organic light-emitting diode of an embodiment;

FIG. 2 is an energy diagram of an organic light-emitting diode of an embodiment;

FIG. 3A is a view showing the relationship between the voltage and current density of a diode according to Example 1;

FIG. 3B is a view showing the relationship between the voltage and luminance of a diode according to Example 1;

FIG. 3C is a view showing the relationship between the luminance and luminous efficacy of a diode according to Example 1;

FIG. 4A is a view showing the relationship between the voltage and current density of a diode according to Example 2;

FIG. 4B is a view showing the relationship between the voltage and luminance of a diode according to Example 2;

FIG. 4C is a view showing the relationship between the luminance and luminous efficacy of a diode according to Example 2;

FIG. 5A is a view showing the relationship between the voltage and current density of a diode according to Comparative Example 1;

FIG. 5B is a view showing the relationship between the voltage and luminance of a diode according to Comparative Example 1;

FIG. 5C is a view showing the relationship between the luminance and luminous efficacy of a diode according to Comparative Example 1;

FIG. 6A is a view showing the relationship between the voltage and current density of a diode according to Comparative Example 2;

FIG. 6B is a view showing the relationship between the voltage and luminance of a diode according to Comparative Example 2;

FIG. 6C is a view showing the relationship between the luminance and luminous efficacy of a diode according to Comparative Example 2; and

FIG. 7 is a view showing the relationship between the film thickness of a second area of an emissive layer and maximum luminous efficacy.

### DETAILED DESCRIPTION

In general, according to one embodiment, there is provided an organic light-emitting diode including an anode and a cathode arranged apart from each other, an emissive layer arranged between the anode and the cathode, a hole injection layer arranged between the anode and the emissive layer and including a polyethylenedioxythiophene, and a hole-transport layer arranged between the hole injection layer and the emissive layer and including a hole-transport material. The emissive layer includes a cathode side first area including a hole transport host material, an electron transport host material and an emitting dopant, and an anode side second area including the hole transport host material and no electron transport host material.

Embodiments of the present invention are explained below in reference to the drawings.

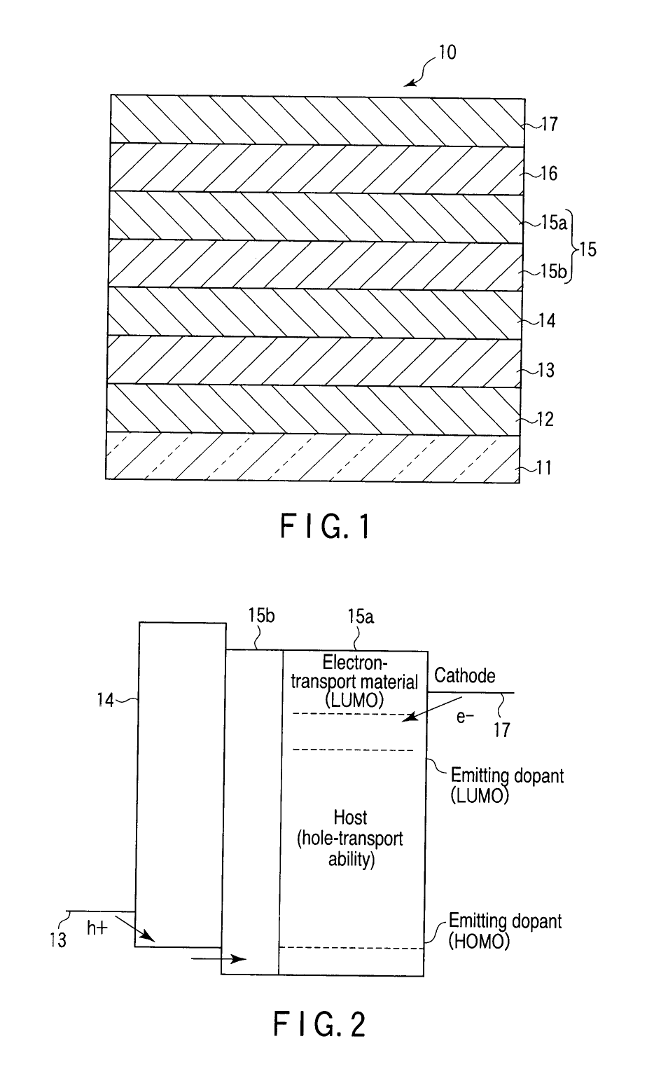

FIG. 1 is a cross-sectional view of the organic light-emitting diode of an embodiment of the present invention.

In the organic light-emitting diode 10, an anode 12, hole injection layer 13, hole transport layer 14, emissive layer 15, electron injection/transport layer 16, and cathode 17 are formed in sequence on a substrate 11. The emissive layer 15 comprises a cathode side first area 15a and an anode side second area 15b. The electron injection/transport layer 16 are formed if necessary.

FIG. 2 is an energy diagram of an organic light-emitting diode of an embodiment.

In this embodiment, the emissive layer 15 comprises two areas, that is, a cathode side first area 15a and an anode side second area 15b. The first area 15a comprises at least one hole transport host material, at least one electron-transport host material and at least one emitting dopant. The second area 15b, on the other hand, comprises the hole transport host material contained in the first area 15a and does not comprise the electron transport host material. When, similarly to the conventional case, the electron transport host material in the emissive layer and the hole transport layer are arranged in contact with each other, an exciplex is formed between the electron transport host material and the hole transport layer, giving rise to the problem concerning a reduction in luminous efficacy. According to the structure of this embodiment, however, the second area 15b comprising an hole transport host material and no electron transport host material is arranged between the first area 15a of the emissive layer comprising an electron transport host material and the hole transport layer 14, thereby making it possible to prevent the formation of an exciplex to suppress a reduction in luminous efficacy.

Each member of the organic light-emitting diode of the embodiment of the present invention is explained below in detail.

The emissive layer 15 receives holes and electrons from the anode and the cathodes, respectively, followed by recombination of holes and electrons which results in the light emission. The energy generated by the recombination excites the host material in the emissive layer. An emitting dopant is excited by energy transfer from the excited host material to the emitting dopant, and the emitting dopant emits light when it returns to the ground state.

The first area 15a of the emissive layer is that in which a host material comprising an organic material is doped with an emissive metal complex comprising iridium or platinum as a central metal. As the host material, at least one hole transport host material and at least one electron transport host material are used.

The organic light-emitting diode emits light when holes and electrons are injected into the emissive layer, where holes are combined with electrons to generate excitons. Therefore, the emissive layer preferably comprises a material which transports both holes and electrons efficiently. However, a few materials having such characteristics are present and it is therefore difficult to find materials having such characteristics as to attain high luminous efficacy. Therefore, in this embodiment, a hole transport host material and an electron transport host material are allowed to be intermingled in the emissive layer, thereby making it possible to transport both holes and electrons efficiently.

Examples of the hole transport host material are shown below.

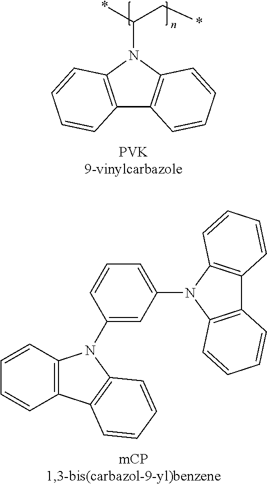

Examples of the electron transport host material are shown below.

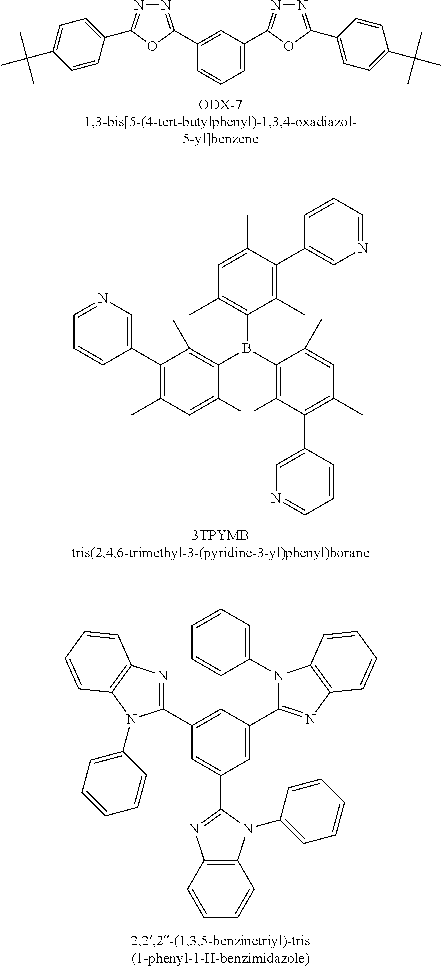

As the emitting dopant, any known light-emitting material may be used. The emitting dopant is preferably phosphorescent emitting dopant having a high internal quantum efficiency though it may be a fluorescent emitting dopant or a phosphorescent emitting dopant. Examples of the emitting dopant include blue-emitting dopants, green-emitting dopants and red-emitting dopants.

Typical examples of the blue-emitting dopant are shown below.

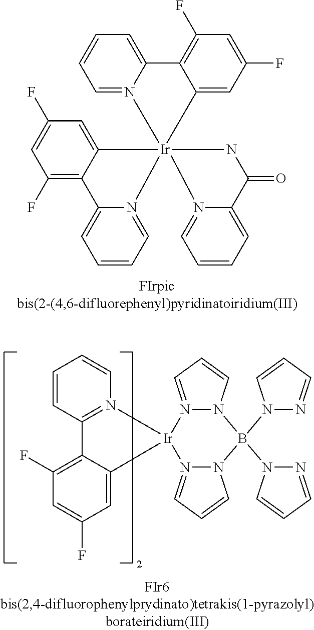

Typical examples of the green-emitting dopant are shown below.

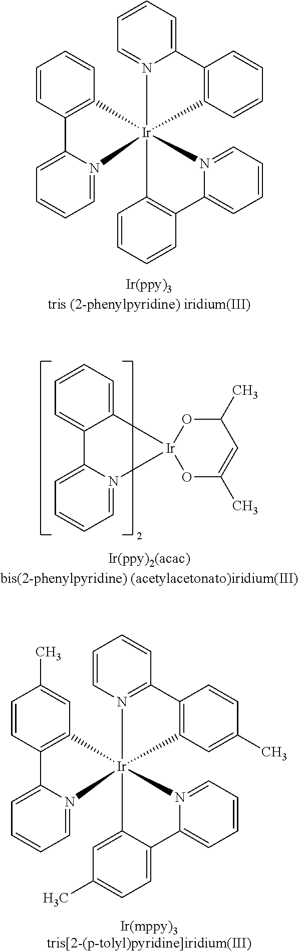

Typical examples of the red-emitting dopant are shown below.

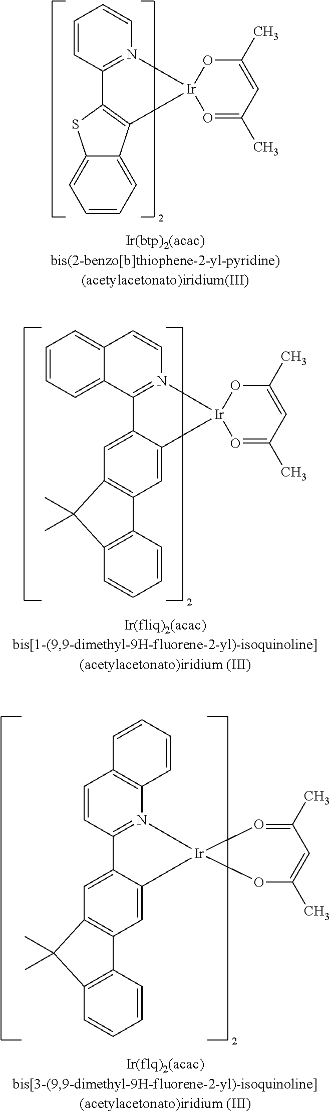

Typical examples of the yellow-emitting dopant are shown below.

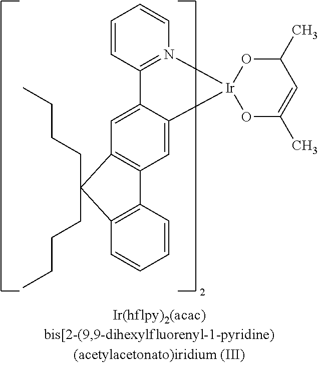

A method for forming the first area of the emissive layer 15a includes, for example, a spin coating method, a vacuum evaporation method and the like, but is not particularly limited thereto as long as it is a method which can form a thin film. A solution comprising an emitting dopant, an electron-transport host material and a hole transport host material is applied in a desired film thickness and dried under heating using a hot plate or the like. As the solution to be applied, one obtained by filtering using a filter in advance may be used.

The thickness of the first area 15a is preferably 5 to 100 nm. Though the ratios of the electron transport host material, hole transport host material and emitting dopant in the first area 15a are arbitrary as long as the effect of the present invention is not impaired, it is preferable that the electron transport host material be 4 to 95% by weight, the hole transport host material be 4 to 95% by weight and the emitting dopant be 1 to 15% by weight. Each concentration of the hole transport host material, electron transport host material and emitting dopant contained in the first area 15a is preferably uniform without any concentration gradient.

The second area of the emissive layer 15b is made of the same material that is used for the hole-transport host material contained in the above first area 15a. The second area 15b may further comprise an emitting dopant. The second area 15b can be formed by the same method as the first area 15a and preferably has a thickness greater than 0 nm and below 20 nm.

The substrate 11 is a member for supporting other members. The substrate 11 is preferably one which is not modified by heat or organic solvents. A material of the substrate 11 includes, for example, an inorganic material such as alkali-free glass and quartz glass; plastic such as polyethylene, polyethylene terephthalate (PET), polyethylene naphthalate (PEN), polyimide, polyamide, polyamide-imide, liquid crystal polymer, and cycloolefin polymer; polymer film; and metal substrate such as SUS and silicon. In order to obtain light emission, a transparent substrate consisting of glass, synthesized resin, and the like is preferably used. Shape, structure, size, and the like of the substrate 11 are not particularly limited, and can be appropriately selected in accordance with application, purpose, and the like. The thickness of the substrate 11 is not particularly limited as long as it has sufficient strength for supporting other members.

The anode 12 is formed on the substrate 11. The anode 12 injects holes into the hole transport layer 13 or the emissive layer 14. A material of the anode 12 is not particularly limited as long as it exhibits conductivity. Generally, a transparent or semitransparent material having conductivity is deposited by vacuum evaporation, sputtering, ion plating, plating, and coating methods, and the like. For example, a metal oxide film and semitransparent metallic thin film exhibiting conductivity may be used as the anode 12. Specifically, a film prepared by using conductive glass consisting of indium oxide, zinc oxide, tin oxide, indium tin oxide (ITO) which is a complex thereof, fluorine doped tin oxide (FTO), indium zinc oxide (IZO), indium gallium zinc oxide (IGZO) and the like; gold; platinum; silver; copper; and the like are used. In particular, it is preferably a transparent electrode consisting of ITO. As an electrode material, organic conductive polymer polyaniline, the derivatives thereof, polythiophene, the derivatives thereof, and the like may be used.

When ITO is used as the anode 12, the thickness thereof is preferably 30-300 nm. If the thickness is thinner than 30 nm, the conductivity is decreased and the resistance is increased, resulting in reducing the luminescent efficiency. If it is thicker than 300 nm, ITO Loses flexibility and is cracked when it is under stress. The anode 12 may be a single layer or stacked layers each composed of materials having various work functions.

Various passivation films, a refractive index matching layer, a color filter layer and the like may be formed between ITO and the substrate and these layers may be formed on the surface opposite to ITO side of the substrate. Further, a circuit using a thin film transistor (TFT) may be used to supply power to ITO and a structure may be used which uses auxiliary wiring to prevent potential drop in the case of high current density. A partition wall made of an insulating layer may be formed at the edge part of the diode.

The hole injection layer 13 is formed on the anode 12. The hole injection layer 13 receives holes from the anode 12 and transports them to the emissive layer side. As a material of the hole injection layer 13, for example, polythiophene type polymer such as a conductive ink, poly(ethylenedioxythiophene):polystyrene sulfonate [hereinafter, referred to as PEDOT:PSS] can be used, but is not limited thereto. The structure formulae of PEDOT and PSS are shown below.

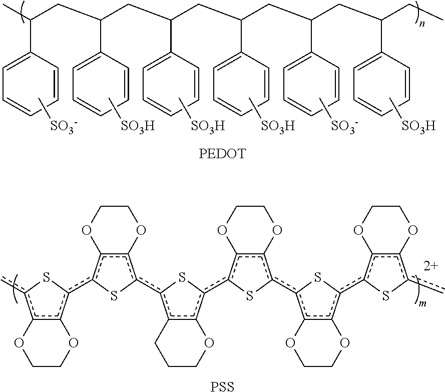

A method for forming the hole injection layer 13 includes, for example, a spin coating method, a slit coater, a meniscus coating method, a gravure printing method, a relief-printing method, a flexo-printing method, an ink jet printing method, a screen printing method and the like, but is not particularly limited thereto as long as it is a method which can form a thin film. When the spin coating method is used, the material of the hole injection layer 13 is applied in a desired film thickness and then, dried under heating by using a hot plate or the like. As the solution to be applied, one obtained by filtering using a filter in advance may be used.

The hole transport layer 14 is formed on the hole injection layer 13. The hole transport layer 14 receives holes from the hole injection layer 13 and transports them to the emissive layer 15. A method for depositing the hole transport layer 14 is similar to that for the hole injection layer 13. Typical examples of the material of the hole transport layer 14 are shown below.

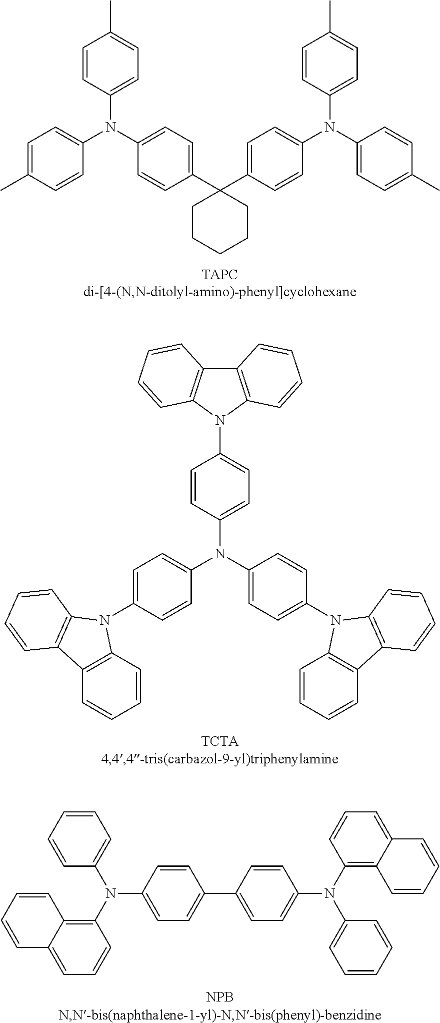

The electron injection/transport layer 16 is optionally arranged between the emissive layer 15 and cathode 17. The electron injection/transport layer 16 receives electrons from the cathode 17 and transports them to the emissive layer side. As a material of the electron injection/transport layer 16 is, for example, CsF, tris(8-hydroxyquinolinato)aluminum [hereinafter, referred to as Alq₃], LiF, and the like, but is not limited thereto. A method for forming the electron injection/transport layer 16 is similar to that for the hole infection layer 13 and the hole transport layer 14.

The cathode 17 is formed on the emissive layer 15 (or the electron injection/transport layer 16). The cathode 17 injects electrons into the emissive layer 15 (or the electron injection/transport layer 16). Generally, a transparent or semitransparent material having conductivity is deposited by vacuum evaporation, sputtering, ion plating, plating, coating methods, and the like. Materials for the cathode include a metal oxide film and semitransparent metallic thin film exhibiting conductivity. When the anode 12 is formed with use of a material having high work function, a material having low work function is preferably used as the cathode 17. A material having low work function includes, for example, alkali metal and alkali earth metal. Specifically, it is Li, In, Al, Ca, Mg, Li, Na, K, Yb, Cs, and the like.

The cathode 17 may be a single layer or stacked layers each composed of materials having various work functions. Further, it may be an alloy of two or more metals. Examples of the include a lithium-aluminum alloy, lithium-magnesium alloy, lithium-indium alloy, magnesium-silver alloy, magnesium-indium alloy, magnesium-aluminum alloy, indium-silver alloy, and calcium-aluminum alloy.

The thickness of the cathode 17 is preferably 20-300 nm. When the thickness is thinner than the aforementioned range, the resistance is excessively high. When the film thickness is thicker, long period of time is required for deposition of the cathode 17, resulting in deterioration of the performance due to damage to the adjacent layers.

In order to inject holes into the hole transport layer from the anode, a highest occupied molecular orbital (HOMO) of the hole transport layer material is preferably a value between the energy level of the anode and a HOMO of the emitting dopant. Similarly, a lowest unoccupied molecular orbital (LUMO) of the electron transport host material is preferably a value between the energy level of the cathode and a LUMO of the emitting dopant or lower than the energy level of the cathode. It is considered that when such a material is used, the energy level of the HOMO of the hole transport layer is inevitably close to the energy level of the LUMO of the electron transport host material so that an exciplex is easily formed. In light of this, the second area of the emissive layer having a deep HOMO, that is, a layer comprising no electron transport host material is formed. As a result, a difference in energy from the LUMO of the electron transport host material contained in the first area of the emissive layer adjacent to the hole transport layer is increased, thereby making it possible to reduce the formation of an exciplex.

Further, when an exciplex is formed, there is a tendency that light emission having higher energy (short wavelength) is obtained when a difference in energy between the HOMO of the hole transport layer material which is to be a donor and the LUMO of the electron transport host material is higher. For this, even when energy is transferred from the exciplex to the emitting dopant, it may be said that the HOMO of the hole transport layer material which is to be a donor is preferably deeper. However, if the HOMO of the second area of the emissive layer comprising no electron-transport host material is deeper than the HOMO of the hole-transport host material in the emissive layer, this is undesirable because holes are injected with low efficiency.

Explained above is an organic light-emitting diode in which an anode is formed on a substrate and a cathode is arranged on the opposite side to the substrate, but the substrate may be arranged on the cathode side.

### EXAMPLES

The present invention will be explained in more detail by way of Examples, which, however, are not intended to be limiting of the technical scope of the present invention.

### Example 1

As Example 1, an organic light-emitting diode was fabricated which comprises a second area of an emissive layer, the second area comprising a hole-transport host material and no electron-transport host material as explained above.

On a glass substrate, an anode made of indium tin oxide (ITO) having a thickness of 50 nm was formed by vacuum evaporation. As the material of the hole injection layer, a polyethylenedioxythiophene:polystyrenesulfonic acid (PEDOT:PSS) was used. An aqueous PEDOT:PSS solution was applied to the anode by spin coating and dried under heating to form a hole injection layer having a thickness of 60 nm. In succession, a hole transport layer having a thickness of 20 nm was formed on the hole injection layer by vacuum evaporation of di-[4-(N,N-ditolylamino) phenyl]cyclohexane (TAPC).

A second area of an emissive layer having a thickness of 10 nm was formed on the hole-transport layer by vacuum evaporation of 1,3-bis(carbazole-9-yl)benzene (mCP) which is a hole-transport host material. For the material of the first area of the emissive layer, mCP was used as a hole-transport host material, bis(2-(4,6-difluorophenyl)pyridinato iridium (III) (FIrpic) was used as a blue-emitting dopant and 1,3-bis[5-tert-butylphenyl]-1,3,4-oxadiazole-5-yl)benzene (OXD-7) was used as an electron-transport host material. These compounds were weighed such that the ratio by weight of these compounds was as follows: mCP:FIrpic:OXD-7=65:5:30, to form a first area of the emissive layer having a thickness of 80 nm on the second area of the emissive layer by co-evaporation of these compounds.

In succession, an electron injection/transport layer having a thickness of 1 nm was formed on the emissive layer by vacuum evaporation of CsF. A cathode having a thickness of 150 nm was formed on the electron injection/transport layer by vacuum evaporation of Al.

The layer structure of this diode is represented as follows: ITO/PEDOT:PSS 60 nm/TAPC 20 nm/mPC 10 nm/mCP:FIrpic:OXD-7 80 nm/CsF 1 nm/Al 150 nm.

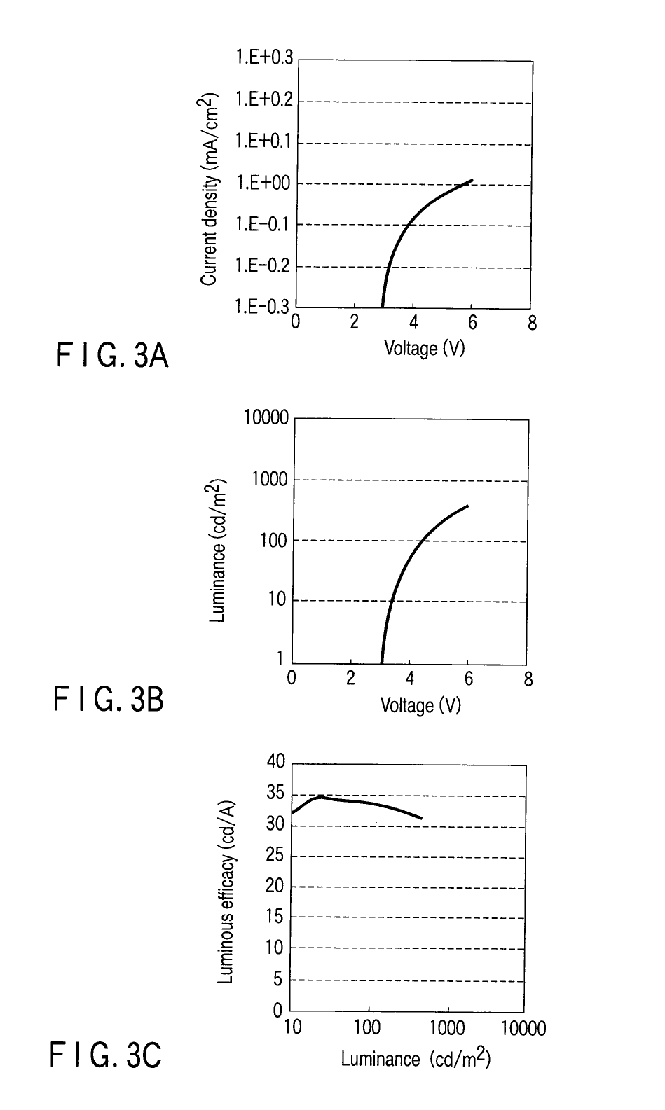

With regard to the organic light-emitting diode fabricated in the above manner, its luminous efficacy was measured. The luminous efficacy was obtained by simultaneous measurements of luminance, current and voltage. The luminance was measured by using a luminance meter (trade name: BM-7, fabricated by TOPCON CORPORATION). Further, the current and voltage were measured by using a Semiconductor Parameter Analyzer 4156B (trade name, fabricated by HP Company). FIG. 3A is a view showing the relationship between the voltage and current density of the diode according to Example 1. FIG. 3B is a view showing the relationship between the voltage and luminance of the diode according to Example 1. FIG. 3C is a view showing the relationship between the luminance and luminous efficacy of the diode according to Example 1. The maximum luminous efficacy of the organic light-emitting diode of Example 1 was 35 cd/A.

### Example 2

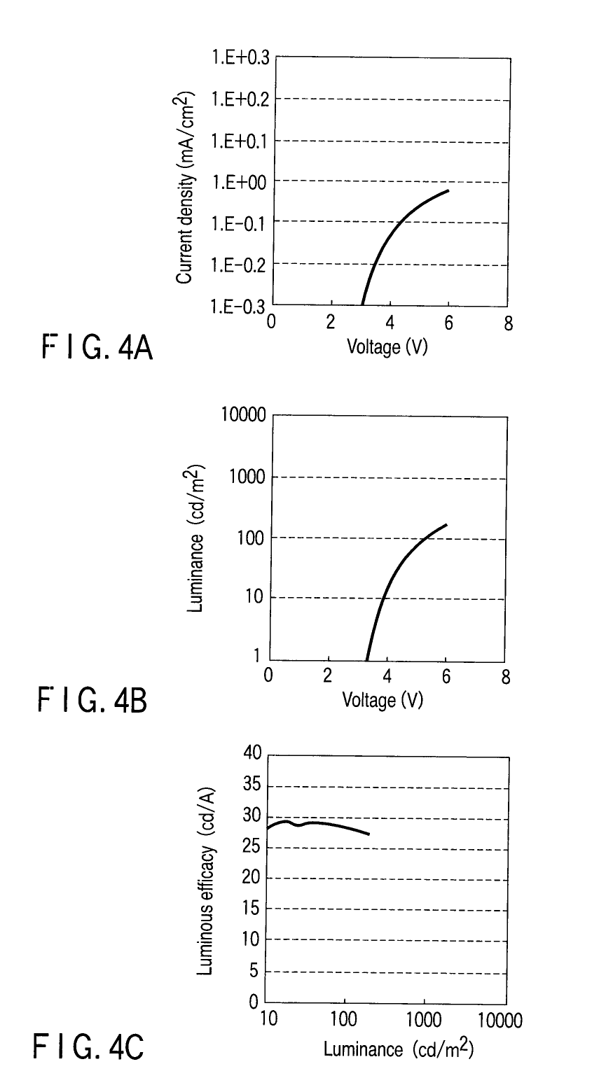

An organic light-emitting diode was fabricated in the same manner as in Example 1 except that the thickness of the second area of the emissive layer was designed to be 20 nm. FIG. 4A is a view showing the relationship between the voltage and current density of the diode according to Example 2. FIG. 4B is a view showing the relationship between the voltage and luminance of the diode according to Example 2. FIG. 4C is a view showing the relationship between the luminance and luminous efficacy of the diode according to Example 2. The maximum luminous efficacy of diode of Example 2 was 29 cd/A.

### Comparative Example 1

For comparison, an organic light-emitting diode comprising neither the hole transport layer nor the second area of the emissive layer was fabricated in the same manner as in Example 1. The layer structure of this diode is as follows: ITO/PEDOT:PSS 60 nm/mCP:FIrpic:OXD-7 80 nm/CsF 1 nm/Al 150 nm.

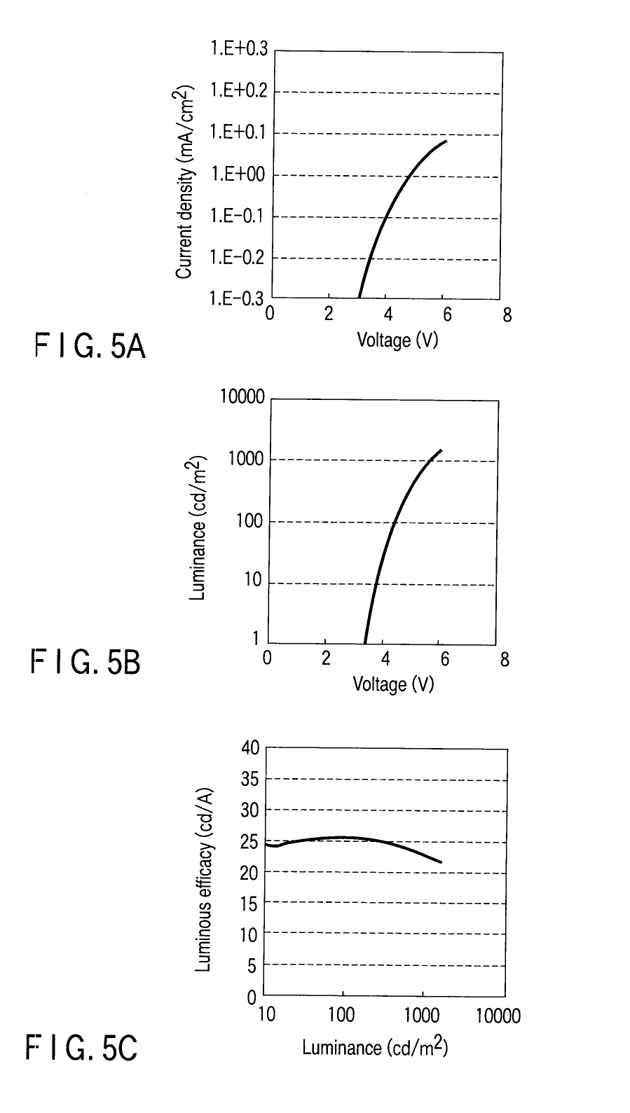

FIG. 5A is a view showing the relationship between the voltage and current density of the diode according to Comparative Example 1. FIG. 5B is a view showing the relationship between the voltage and luminance of the diode according to Comparative Example 1. FIG. 5C is a view showing the relationship between the luminance and luminous efficacy of the diode according to Comparative Example 1. With regard to this diode, the maximum luminous efficacy was 25 cd/A.

### Comparative Example 2

For comparison, an organic light-emitting diode comprising no second area of the emissive layer was fabricated in the same manner as in Example 1. The layer structure of this diode is as follows: ITO/PEDOT:PSS 60 nm/TAPC 20 nm/mCP:FIrpic:OXD-7 80 nm/CsF 1 nm/Al 150 nm.

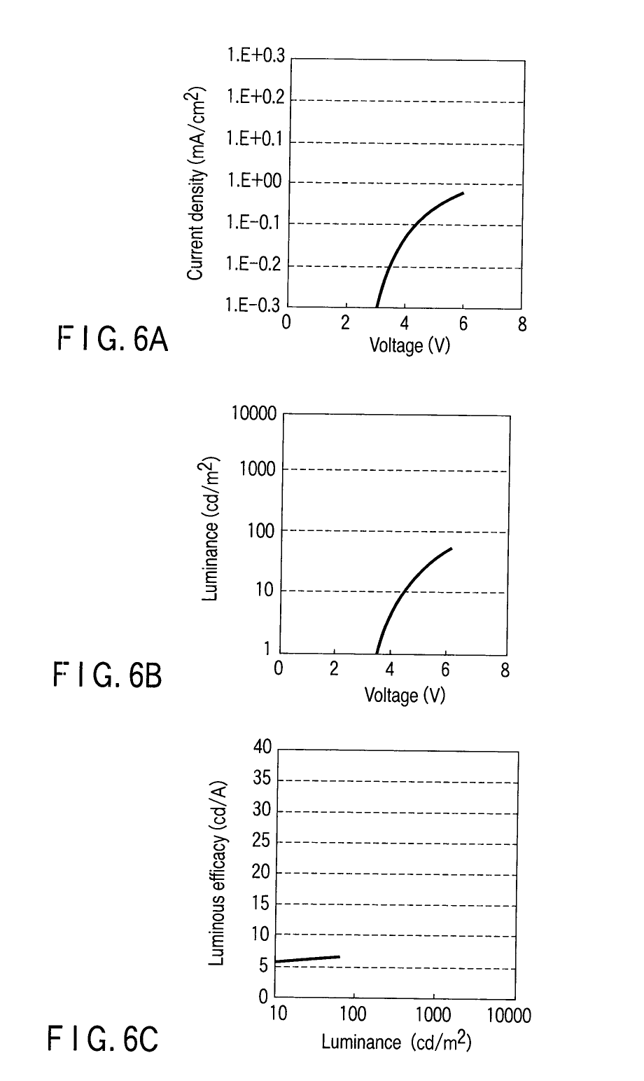

FIG. 6A is a view showing the relationship between the voltage and current density of the diode according to Comparative Example 2. FIG. 6B is a view showing the relationship between the voltage and luminance of the diode according to Comparative Example 2. FIG. 6C is a view showing the relationship between the luminance and luminous efficacy of the diode according to Comparative Example 2. With regard to this diode, the maximum luminous efficacy was 6 cd/A.

It was confirmed from the results of the measurement that the organic light-emitting diode of Examples 1 and 2 exhibited a higher luminous efficacy than each organic light-emitting diode obtained in Comparative Examples 1 and 2. When the results of Comparative Examples 1 and 2 are compared with each other, it is found that the organic light-emitting diode of Comparative Example 2 provided with the hole-transport layer is more dropped in luminous efficacy. This reason is considered to be that an exciplex was formed between OXD-7 which is the electron-transport host material and TAPC which is the hole-transport layer material.

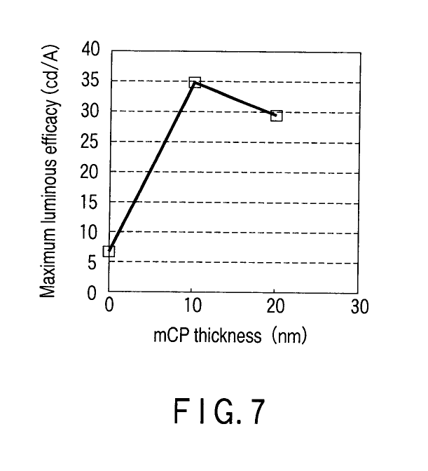

Next, the maximum luminous efficacy of the organic light-emitting diodes of Examples 1 and 2 were compared with each other to determine the optimum film thickness of the second area of the emissive layer. FIG. 7 is a view showing the relationship between the film thickness of the second area of the emissive layer and the maximum luminous efficacy. It is found from FIG. 7 that Example 2 in which the film thickness of the second area of the emissive layer is 20 nm is more reduced in luminous efficacy than Example 1 in which the film thickness of the second area of the emissive layer is 10 nm. The thickness of the second area of the emissive layer is preferably less than 20 nm.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic light-emitting diode comprising:
an anode and a cathode arranged apart from each other;
an emissive layer arranged between the anode and the cathode, the emissive layer comprising a cathode side first area and an anode side second area, the cathode side first area comprising a hole transport host material, an electron transport host material and an emitting dopant, the anode side second area comprising the hole transport host material and no electron transport host material;
a hole injection layer arranged between the anode and the emissive layer and comprising a polyethylenedioxythiophene; and
a hole-transport layer arranged between the hole injection layer and the emissive layer and comprising a hole-transport material.

2. The organic light-emitting diode according to claim 1, wherein the second area of the emissive layer further comprises an emitting dopant.

3. The organic light-emitting diode according to claim 1, wherein the hole transport host material, the electron transport host material and the emitting dopant which are contained in the first area of the emissive layer each have a uniform concentration in the first area.

4. The organic light-emitting diode according to claim 1, wherein the film thickness of the second area of the emissive layer is 20 nm or less.
